(19) United States
(12) Patent Application Publication
(10) Pub. No.: US 2008/0076256 A1
(43) Pub. Date: Mar. 27, 2008

(54) Via hole forming method

(75) Inventors: Akihito Kawai, Tokyo (JP); Takashi Ono, Tokyo (JP); Hiroshi Morikazu, Tokyo (JP)

Correspondence Address: SMITH, GAMBRELL & RUSSELL, 1130 CONNECTICUT AVENUE, N.W., SUITE 1130, WASHINGTON, DC, 20036, US

(73) Assignee: Disco Corporation

(21) Appl. No.: 11/902,046

(22) Filed: Sep. 18, 2007

(30) Foreign Application Priority Data
Sep. 22, 2006 (JP) 2006-257082

(51) Int. Cl. H01L 21/311

(52) U.S. Cl. 438/701; 257/E21.249

(57) ABSTRACT

A method of forming a via hole reaching a bonding pad in a wafer, which have a plurality of devices on the front surface of a substrate and bonding pads on each of the devices, by applying a pulse laser beam from the rear surface of the substrate, comprising the steps of:

affixing a protective member to the front surface of the substrate;

grinding the rear surface of the substrate having the protective member affixed to the front surface to reduce the thickness of the wafer to a predetermined value;

forming via holes in the substrate by applying a pulse laser beam from the rear surface of the substrate of the wafer having the predetermined thickness; and

etching the wafer having the via holes in the substrate from the rear surface of the substrate.

### FIELD OF THE INVENTION

The present invention relates to a method of forming a via hole in a wafer having a plurality of devices on the front surface of a substrate and bonding pads on each of the devices by applying a pulse laser beam from the rear surface of the substrate.

### DESCRIPTION OF THE PRIOR ART

In the production process of a semiconductor device, a plurality of areas are sectioned by dividing lines called “streets” arranged in a lattice pattern on the front surface of a substantially disk-like semiconductor wafer, and a device such as IC, LSI or the like is formed in each of the sectioned areas. Individual semiconductor chips are manufactured by cutting this semiconductor wafer along the streets to divide it into areas each having a device thereon.

To reduce the size and assure the high functions of an apparatus, a modular structure, where a plurality of semiconductor chips are laminated and connect up the bonding pads of the laminated semiconductor chips, has been utilized and disclosed by JP-A2003-163323, for example. This modular structure is such that a plurality of devices are formed on the front surface of a substrate constituting a semiconductor wafer, bonding pads are formed on each of the devices, via holes reaching the bonding pads are formed from the rear side of the substrate at positions where the bonding pads have been formed, and a conductive material such as aluminum, copper or the like to be connected to the bonding pads is buried in the via holes.

The via holes in the above semiconductor wafer are generally formed by a drill. However, the diameters of the via holes formed in the semiconductor wafer are as small as 100 to 300 μm, and forming the via holes by drilling is not always satisfactory in terms of productivity.

To solve the above problem, the applicant of the present application has proposed as JP-A 2007-67082 a method of efficiently forming via holes in a wafer having a plurality of devices on the front surface of a substrate and bonding pads on each of the devices by applying a pulse laser beam from the rear surface of the substrate.

There is a problem in decreasing the quality of each device that the inner walls of the via holes formed by applying a pulse laser beam from the rear surface of the substrate of the wafer are rough and debris which is produced by the application of the pulse laser beam accumulates around the openings of the via holes on the rear surface of the substrate.

### SUMMARY OF THE INVENTION

It is an object of the present invention to provide a via hole forming method which is capable of making smooth the inner walls of via holes and the portions around the openings of the via holes.

To attain the above object, according to the present invention, there is provided a method of forming a via hole reaching a bonding pad in a wafer having a plurality of devices on the front surface of a substrate and bonding pads on each of the devices by applying a pulse laser beam from the rear surface of the substrate, comprising the steps of:

affixing a protective member to the front surface of the substrate;

grinding the rear surface of the substrate having the protective member affixed to the front surface to reduce the thickness of the wafer to a predetermined value;

forming via holes in the substrate by applying a pulse laser beam from the rear surface of the substrate of the wafer which has been formed in the predetermined thickness; and

etching the wafer having the via holes in the substrate from the rear surface of the substrate.

Preferably, plasma etching is carried out in the above etching step.

Preferably, the wafer has a device area where the plurality of devices have been formed and a peripheral excess area surrounding the device area on the front surface of the substrate, and the rear surface grinding step is to grind an area corresponding to the device area on the rear surface of the substrate so as to reduce the thickness of the wafer to a predetermined value and to keep an area corresponding to the peripheral excess area on the rear surface of the substrate as an annular reinforcing portion.

The above via hole forming step is to form via holes not reaching the bonding pads, leaving the remaining portions behind, and the etching step is to form via holes reaching the bonding pads by etching the remaining portions.

In the via hole forming method of the present invention, the step of forming via holes in the substrate by applying a pulse laser beam from the rear surface of the substrate of the wafer is followed by the step of etching the wafer having the via holes in the substrate from the rear surface of the substrate. Therefore, grinding distortion which is generated in the rear surface of the substrate of the wafer in the rear surface grinding step is removed and also debris which accumulates around the openings of the via holes by carrying out the via hole forming step is removed. Since the inner walls of the via holes are etched by carrying out the etching step, the rough inner walls of the via holes are made smooth, and via holes having a smooth inner wall can be formed.

### BRIEF DESCRIPTION OF THE DRAWINGS

FIG. 1 is a perspective view of a semiconductor wafer as a wafer to be processed by the via hole forming method of the present invention;

FIG. 2 is a perspective view of the semiconductor wafer whose front surface is affixed a protective member thereon by carrying out the protective member affixing step in the via hole forming method of the present invention;

FIG. 3 is a explanatory diagram showing the state where a first embodiment of the rear surface grinding step in the via hole forming method of the present invention;

FIG. 4 is a explanatory diagram showing a second embodiment of the rear surface grinding step in the via hole forming method of the present invention;

FIG. 5 is a sectional view of the semiconductor wafer which has undergone the rear surface grinding step shown in FIG. 4;

FIG. 6 is a perspective view of the principal portion of a laser beam processing machine for carrying out the via hole forming step in the via hole forming method of the present invention;

FIG. 7 is a explanatory diagram showing the via hole forming step in the via hole forming method of the present invention;

FIG. 8 is a partially enlarged sectional view of the semiconductor wafer in which via holes are formed by carrying out the via hole forming step in the via hole forming method of the present invention;

FIGS. 9(a) and 9(b) are enlarged sectional views of other examples of via holes formed by the via hole forming step in the via hole forming method of the present invention;

FIG. 10 is a sectional view of a plasma etching apparatus for carrying out the etching step in the via hole forming method of the present invention;

FIG. 11 is a sectional view of a lower electrode and an electrostatic chuck table mechanism provided in the plasma etching apparatus shown in FIG. 10;

FIG. 12 is a sectional view showing the state where the plasma etching is being carried out by the plasma etching apparatus shown in FIG. 10; and

FIG. 13 is a partially enlarged sectional view showing the state where the semiconductor wafer having via holes shown in FIG. 8 has undergone the etching step.

### DETAILED DESCRIPTION OF THE PREFERRED EMBODIMENTS

The via hole forming method of the present invention will be described in more detail hereinbelow with reference to the accompanying drawings.

FIG. 1 is a perspective view of a semiconductor wafer 2 as the wafer to be processed by the via hole forming method of the present invention. In the semiconductor wafer 2 shown in FIG. 1, a plurality of areas are sectioned by a plurality of streets 22 arranged in a lattice pattern on the front surface 21a of a substrate 21 made of silicon and having a thickness of, for example, 350 μm, and a device 23 such as IC, LSI or the like is formed in each of the sectioned areas. The devices 23 are all the same in structure. A plurality of bonding pads 24 are formed on the surface of each device 23. The bonding pads 24 are made of a metal material such as aluminum, copper, gold, platinum, nickel or the like and have a thickness of 5 μm. The semiconductor wafer 2 constituted as described above has a device area 25 where the devices 23 are formed and a peripheral excess area 26 surrounding the device area 25.

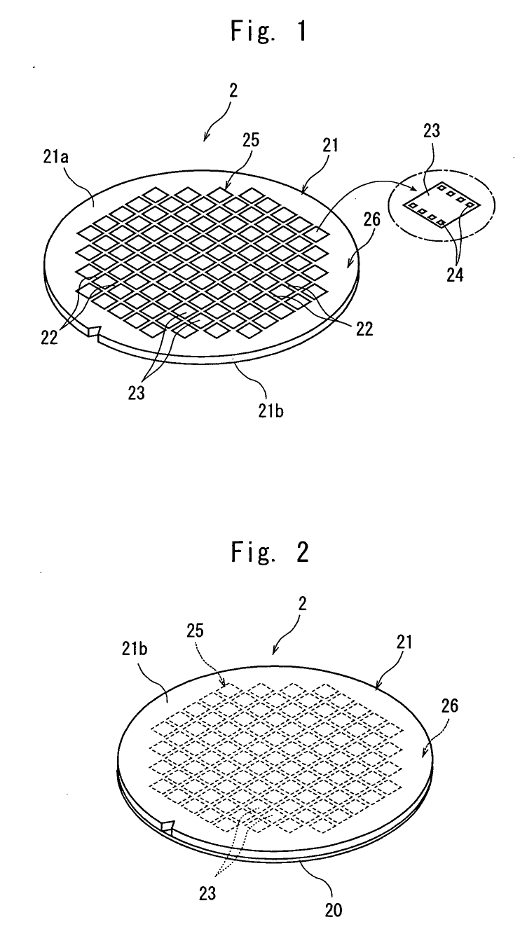

Via holes reaching the bonding pads 24 are formed in the substrate 21 of the above semiconductor wafer 2. To form the via holes, as shown in FIG. 2, a protective member 20 is affixed to the front surface 21a of the substrate 21 of the semiconductor wafer 2 (protective member affixing step). Therefore, the rear surface 21b of the substrate 21 of the semiconductor wafer 2 is exposed.

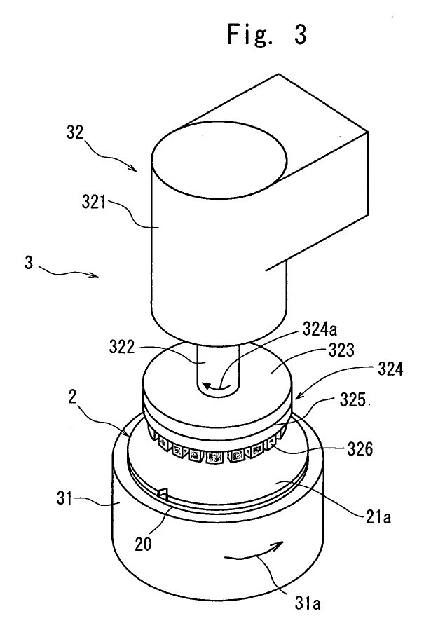

The protective member affixing step is followed by the step of grinding the rear surface 21b of the substrate 21 of the semiconductor wafer 2 to reduce the thickness of the substrate 21 to a predetermined value. This rear surface grinding step is carried out by using a grinding machine 3 shown in FIG. 3, for example. The grinding machine 3 shown in FIG. 3 comprises a chuck table 31 for holding a wafer as a workpiece and a grinding means 32 for grinding the processing surface of the wafer held on the chuck table 31. The chuck table 31 suction holds the wafer on the top surface and is rotated in a direction indicated by an arrow 31a in FIG. 3. The grinding means 32 comprises a spindle housing 321, a rotary spindle 322 which is rotated by a drive mechanism (not shown) and rotatably supported to the spindle housing 321, a mounter 323 attached to the lower end of the rotary spindle 322 and a grinding wheel 324 mounted onto the under-surface of the mounter 323. The grinding wheel 324 is composed of a disk-like base 325 and an annular grindstone 326 mounted onto the under-surface of the base 325, and the base 325 is mounted onto the under-surface of the mounter 323.

To carry out the rear surface grinding step by using the above grinding machine 3, the protective member 20 side of the above semiconductor wafer 2 carried by a wafer transfer means (not shown) is first placed on the top surface (holding surface) of the chuck table 31 and suction held on the chuck table 31. After the semiconductor wafer 2 is suction held on the chuck table 31, the grinding wheel 324 is rotated at, for example, 6,000 rpm in a direction indicated by an arrow 324a and moved down to bring the grindstone 326 into contact with the rear surface 21b of the substrate 21 of the semiconductor wafer 2 in such a manner that it passes over the center of rotation and the periphery of the rear surface 21b while the chuck table 31 is rotated at, for example, 300 rpm in the direction indicated by the arrow 31a. The grinding wheel 324 is moved down a predetermined distance at a predetermined rate. Thus, the rear surface 21b of the substrate 21 of the semiconductor wafer 2 is ground to reduce the thickness of the substrate 21 to a predetermined value (for example, 100 μm).

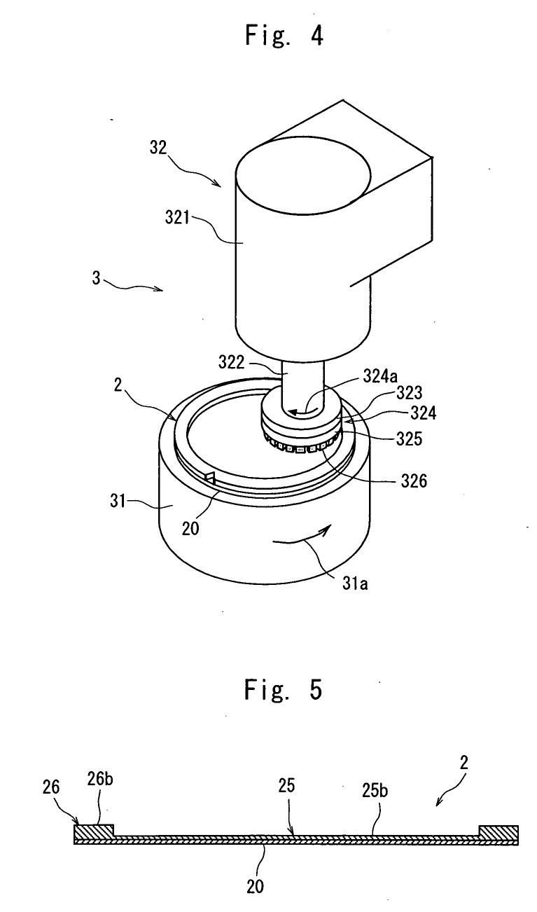

When the rear surface 21b of the substrate 21 of the semiconductor wafer 2 is ground to reduce the thickness of the substrate 21 to about 60 μm, the stiffness of the semiconductor wafer 2 is decreased, thereby making it very difficult to transfer the semiconductor wafer 2. Then, another embodiment of the rear surface grinding step which enables the stiffness of the semiconductor wafer 2 to be maintained even when the rear surface 21b of the substrate 21 of the semiconductor wafer 2 is ground to reduce the thickness of the substrate 21 to 100 μm or less will be described with reference to FIG. 4.

In the embodiment shown in FIG. 4, an area corresponding to the device area 25 on the rear surface 21b of the substrate 21 of the above semiconductor wafer 2 is ground to reduce the thickness of the device area 25 to a predetermined value (for example, 100 μm) and an area corresponding to the peripheral excess area 26 on the rear surface 21b of the substrate 21 is kept as an annular reinforcing portion. Although a grinding machine 3 similar to the grinding machine 3 shown in FIG. 3 may be used even in the embodiment shown in FIG. 4, in the embodiment shown in FIG. 4, the outer diameter of the grindstone 326 of the grinding wheel 324 is set as follows. That is, the outer diameter of the grindstone 326 is smaller than the diameter of the boundary between the device area 25 and the peripheral excess area 26 of the semiconductor wafer 2 and larger than the radius of the boundary so that the annular grindstone 326 passes over the center P1 of rotation of the chuck table 31 (the center of the semiconductor wafer 2).

Also in the embodiment shown in FIG. 4, after the semiconductor wafer 2 is suction held on the chuck table 31, the grinding wheel 324 is rotated at, for example, 6,000 rpm in the direction indicated by the arrow 324a and moved down to bring the grindstone 326 into contact with the rear surface 21b of the substrate 21 of the semiconductor wafer 2 while the chuck table 31 is rotated at, for example, 300 rpm in the direction indicated by the arrow 31a. The grinding wheel 324 is moved down a predetermined distance at a predetermined rate. As a result, the area corresponding to the device area 25 is ground and removed as shown in FIG. 5 to form a circular recess portion 25b having a predetermined thickness (for example, 60 μm) in the rear surface 21b of the substrate 21 of the semiconductor wafer 2, and the area corresponding to the peripheral extra area 26 is kept as an annular reinforcing portion 26b having a thickness of 350 μm in the illustrated embodiment. Thus, in the embodiment shown in FIG. 4, even when the area corresponding to the device area 25 on the rear surface 21b of the substrate 21 of the semiconductor wafer 2 is formed as thick as 100 μm, the area corresponding to the peripheral excess area 26 is kept as the annular reinforcing portion 26b, whereby the stiffness of the semiconductor wafer 2 is maintained, thereby making it possible to carry out the transfer of the semiconductor wafer 2 and other work in the subsequent steps smoothly.

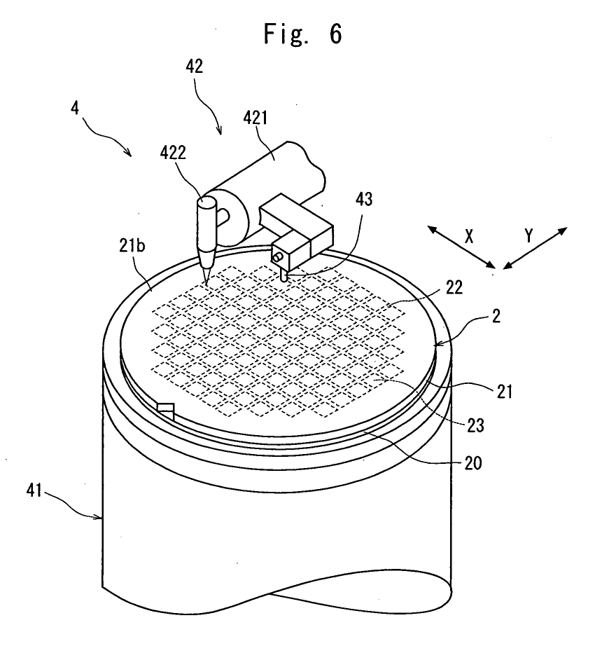

After the step of grinding the rear surface 21b of the substrate 21 of the semiconductor wafer 2 to reduce the thickness of the wafer to a predetermined value as described above, next comes the step of forming via holes in the substrate 21 by applying a pulse laser beam to the rear surface 21b of the substrate 21 of the semiconductor wafer 2. This via hole forming step is carried out by using a laser beam processing machine 4 shown in FIG. 6. The laser beam processing machine 4 shown in FIG. 6 comprises a chuck table 41 for holding a workpiece and a laser beam application means 42 for applying a laser beam to the workpiece held on the chuck table 41. The chuck table 41 is designed to suction hold the workpiece and to be moved in a feed processing direction indicated by an arrow X in FIG. 6 by a processing feed mechanism (not shown) and an indexing feed direction indicated by an arrow Y by an indexing feed mechanism that is not shown.

The above laser beam application means 42 applies a pulse laser beam from a condenser 422 attached to the end of a cylindrical casing 421 arranged substantially horizontally. The illustrated laser beam processing machine 4 comprises an image pick-up means 43 mounted on the end portion of the casing 421 constituting the above laser beam application means 42. This image pick-up means 43 comprises an infrared illuminating means for applying infrared radiation to the workpiece, an optical system for capturing infrared radiation applied by the infrared illuminating means, and an image pick-up device (infrared CCD) for outputting an electric signal corresponding to infrared radiation captured by the optical system, in addition to an ordinary image pick-up device (CCD) for picking up an image with visible radiation. An image signal is supplied to a control means that is not shown.

A description is subsequently given of the step of forming via holes in the substrate 21 of the above semiconductor wafer 2 by using the above-described laser beam processing machine 4.

The protective member 20 side of the above semiconductor wafer 2 is first placed on the chuck table 41 of the laser beam processing machine 4 shown in FIG. 6, and the semiconductor wafer 2 is suction held on the chuck table 41. Therefore, the semiconductor wafer 2 which has undergone the above rear surface grinding step is held in such a manner that the rear surface 21b of the substrate 21 faces up.

The chuck table 41 suction holding the semiconductor wafer 2 as described above is positioned right below the image pick-up means 43 by the feed mechanism that is not shown. After the chuck table 41 is positioned right below the image pick-up means 43, the semiconductor wafer 2 on the chuck table 41 is supposed to be located at a predetermined coordinate position. In this state, alignment work for checking whether the streets 22 formed in a lattice pattern on the semiconductor wafer 2 held on the chuck table 41 are parallel to the X direction and the Y direction is carried out. That is, the image pick-up means 43 picks up an image of the semiconductor wafer 2 held on the chuck table 41 and carries out image processing such as pattern matching to perform the alignment work. Although the front surface 21a, on which the streets 22 are formed, of the substrate 21 of the semiconductor wafer 2 faces down at this point, an image of the streets 22 can be picked up through the rear surface 21b of the substrate 21 as the image pick-up means 43 comprises an infrared illuminating means, an optical system for capturing infrared radiation and an image pick-up device (infrared CCD) for outputting an electric signal corresponding to the infrared radiation as described above.

By carrying out the above-described alignment work, the semiconductor wafer 2 held on the chuck table 41 is located at the predetermined coordinate position. Data on the designed coordinate positions of the plurality of bonding pads 24 formed on the devices 23 on the front surface 21a of the substrate 21 of the semiconductor wafer 2 are stored in the control means (not shown) of the laser beam processing machine 4 in advance.

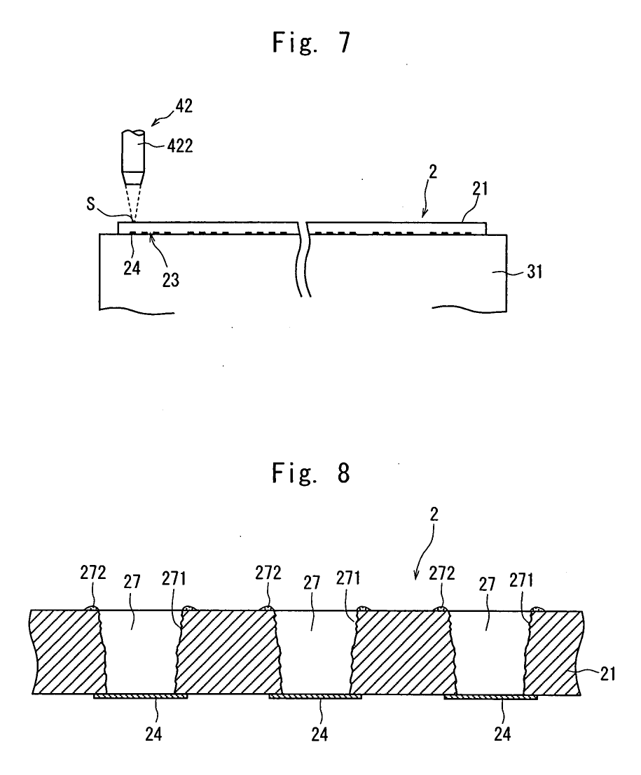

After the above alignment work is carried out, the chuck table 41 is moved as shown in FIG. 7 to position a device 23 at the most left end in FIG. 7 out of the plurality of devices 23 formed in a predetermined direction on the substrate 21 of the semiconductor wafer 2 right below the condenser 422. Then, a bonding pad 24 at the most left end out of the plurality of bonding pads 24 formed on the device 23 at the most left end in FIG. 7 is positioned right below the condenser 422.

Thereafter, a via hole reaching the bonding pad 24 is formed in the substrate 21 by applying a pulse laser beam from the rear surface 21b of the substrate 21. That is, the energy density of the pulse laser beam applied from the condenser 422 of the laser beam application means 42 is set to a value (30 to 40 J/cm² per pulse) with which the semiconductor substrate made of silicon can be processed efficiently but a metal material such as aluminum or the like is hardly processed. A predetermined number of pulses of the pulse laser beam are applied from the condenser 422 of the laser beam application means 42 from the rear surface 21b of the substrate 21.

The processing conditions of the above via hole forming step are set as follows, for example.
Light source of laser beam: YVO4 laser or YAG laser Wavelength: 355 nm
Energy density per pulse: 35 J/cm²

Spot diameter: 70 μm

Under the above processing conditions, when the substrate 21 of the semiconductor wafer 2 is made of silicon, a hole having a depth of 5 μm can be formed with one pulse of the pulse laser beam by setting the spot S having the above diameter to the rear surface 21b (top surface) of the substrate 21. Therefore, by applying 20 pulses of the pulse laser beam, via holes 27 reaching the bonding pads 24 can be formed in the substrate 21 having a thickness of 100 μm as shown in FIG. 8. The inner walls 271 of the via holes 27 formed as described above are rough as shown in FIG. 8 and debris 272 produced by the application of the pulse laser beam accumulates around the openings of the via holes 27 on the rear surface 21b of the substrate 21.

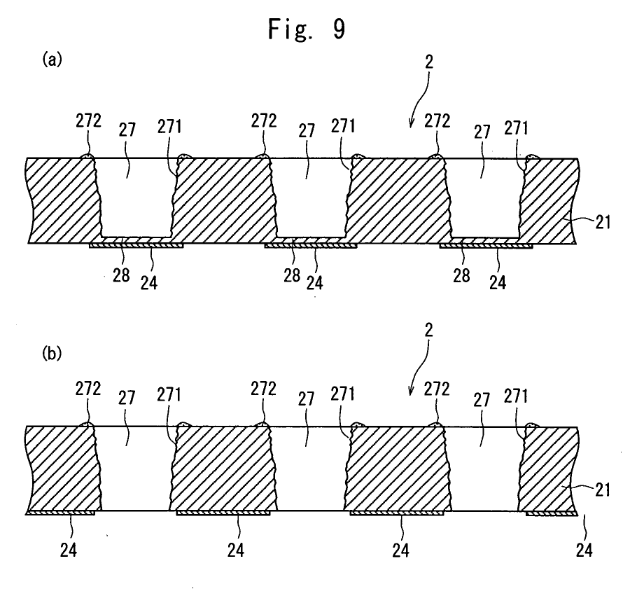

A description is subsequently given of other examples of the via holes 27 formed in the via hole forming step with reference to FIGS. 9(a) and 9(b).

FIG. 9(a) shows an example that the via holes 27 formed in the substrate 21 of the semiconductor wafer 2 do not reach the bonding pads 24 and remaining portions 28 exist.

FIG. 9(b) shows another example that the via holes 27 formed in the substrate 21 of the semiconductor wafer 2 extend through the substrate 21 at positions adjacent to the bonding pads 24.

The inner walls 271 of all the above via holes 27 are rough as shown in FIGS. 9(a) and 9(b) and debris 272 produced by the application of the pulse laser beam accumulates around the openings of the via holes 27 on the rear surface 21b of the substrate 21 like the via holes 27 shown in FIG. 8.

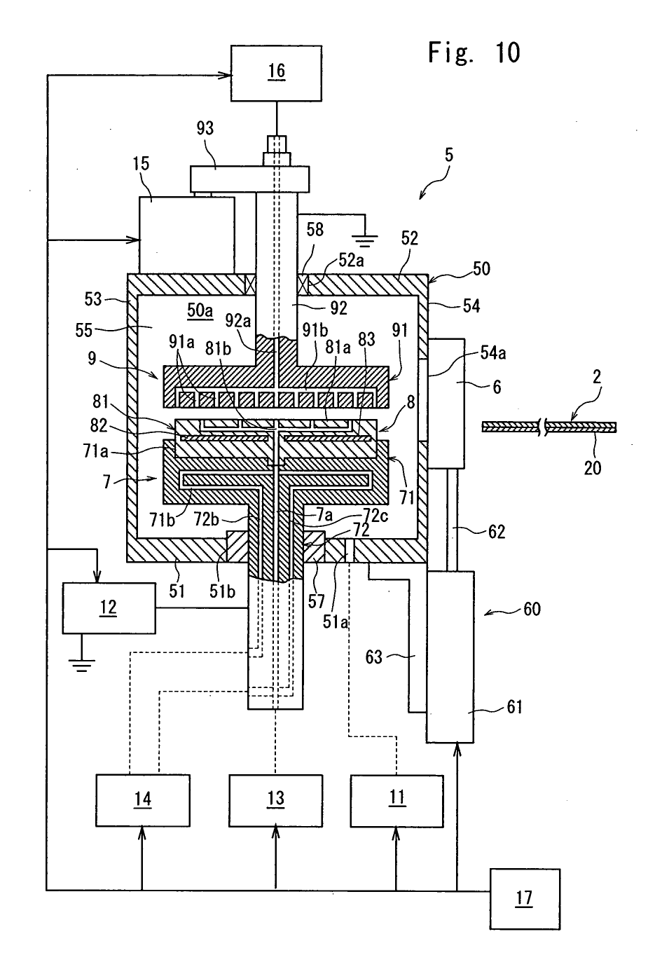

Next comes the step of etching from the rear surface 21b of the substrate 21 to make smooth the rough inner walls 271 of the via holes 27 formed by carrying out the above via hole forming step and to remove the debris 272 which accumulates around the openings of the via holes 27 on the rear surface 21b of the substrate 21. This etching step is carried out by using a plasma etching apparatus 5 shown in FIG. 10.

The plasma etching apparatus 5 shown in FIG. 10 comprises a housing 50 for forming a closed space 50a. This housing 50 has a bottom wall 51, a top wall 52, right and left side walls 53 and 54, a rear side wall 55 and a front side wall (not shown), and an opening 54a for carrying in and out a workpiece is formed in the right side wall 54. A gate 6 for opening and closing the opening 54a is provided on the outer side of the opening 54a in such a manner that it can move in the vertical direction. This gate 6 is moved by gate moving means 60. The gate moving means 60 is composed of an air cylinder 61 and a piston rod 62 connected to a piston (not shown) installed in the air cylinder 61. The air cylinder 61 is mounted onto the bottom wall 51 of the above housing 50 through a bracket 63, and the end (top end in FIG. 10) of the piston rod 62 is connected to the above gate 6. When the gate 3 is opened by this gate moving means 60, the workpiece can be carried in and out through the opening 54a as will be described later. An exhaust port 51a is formed in the bottom wall 51 constituting the housing 50 and connected to a gas exhaust means 11.

A lower electrode 7 and an upper electrode 9 are installed in the closed space 50a formed by the above housing 50 in such a manner that they are opposed to each other. The lower electrode 7 is made of a conductive material and composed of a disk-like chuck table holding portion 71 and a columnar support portion 72 projecting from the center portion of the under surface of the chuck table holding portion 71. The support portion 72 of the lower electrode 7 composed of the disk-like chuck table holding portion 71 and the columnar support portion 72 is inserted into a hole 51b formed in the bottom wall 51 of the housing 50 and supported in the bottom wall 51 by an insulator 57 in a sealed state. The lower electrode 7 supported in the bottom wall 51 of the housing 50 is electrically connected to a high-frequency power source 12 through the support portion 72.

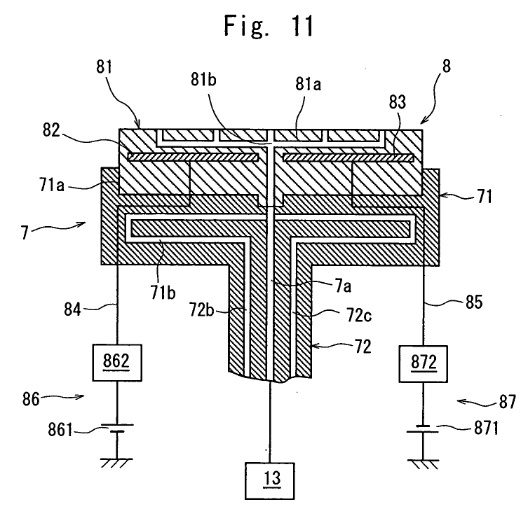

A circular fitting recess portion 71a which is open at the top as shown in FIG. 11 is formed in the top portion of the chuck table holding portion 71 constituting the lower electrode 7, and a chuck table 81 constituting an electrostatic chuck table mechanism 8 is fitted in the fitting recess portion 71a. The chuck table 81 is made of a ceramic material having a resistance of 10¹³ Ωcm in the illustrated embodiment, is formed like a disk having a size corresponding to the above fitting recess portion 71a and is fitted in the fitting recess portion 71a. Electrodes 82 and 83 which generate charge when voltage is applied thereto are installed in the chuck table 81 made of a ceramic material. The electrodes 82 and 83 are connected to DC voltage application means 86 and 87 through conductive wires 84 and 85, respectively. The DC voltage application means 86 and 87 are each composed of DC power sources 861 and 871 and drive circuits 862 and 872, and apply positive (+) voltage to the above electrodes 82 and negative (−) voltage to the above electrode 83 when the drive circuits 862 and 872 are turned on, respectively. As a result, positive (+) and negative (−) charges are generated between the holding surface 81a of the chuck table 81 and the workpiece placed on the holding surface 81a so that the workpiece is suction held on the holding surface 81a by Johnsen-Rahbek force applied therebetween. The above electrode structure is a bipolar electrode structure in the above embodiment but may be a unipolar electrode structure.

The top surface of the chuck table 81 serves as the holding surface 81a for holding the workpiece. A plurality of suction paths 81b which are open to the holding surface 81a are formed in this chuck table 81.

Meanwhile, a communication path 7a communicating with the above suction paths 81b is formed in the chuck table holding portion 71 and the support portion 72 constituting the lower electrode 7. This communication path 7a is connected to a suction means 13.

A cooling path 71b is formed in the lower portion of the chuck table holding portion 71 of the lower electrode 7. One end of the cooling path 71b is connected to a refrigerant introduction path 72b formed in the support portion 72 and the other end of the cooling path 71b is connected to a refrigerant exhaust path 72c formed in the support portion 72. The refrigerant introduction path 72b and the refrigerant exhaust path 72c are connected to a refrigerant supply means 14 as shown in FIG. 10. Therefore, when the refrigerant supply means 14 is activated, a refrigerant is circulated through the refrigerant introduction path 72b, the cooling path 71b and the refrigerant exhaust path 72c. As a result, heat generated by plasma etching which will be described later is transmitted from the lower electrode 7 to the refrigerant, thereby preventing an abnormal rise in the temperature of the lower electrode 7.

The above upper electrode 9 is made of a conductive material and composed of a disk-like gas ejection portion 91 and a columnar support portion 92 projecting from the center portion of the top surface of the gas ejection portion 91. The upper electrode 9 composed of the gas ejection portion 91 and the columnar support portion 92 is arranged such that the gas ejection portion 91 is opposed to the chuck table holding portion 71 of the lower electrode 7, and the support portion 92 is inserted into a hole 52a formed in the top wall 52 of the housing 50 and supported by a sealing member 58 fitted in the hole 52a in such a manner that it can move in the vertical direction. A working member 93 is mounted on the top end of the support portion 92 and connected to a lifting drive means 15. The upper electrode 9 is grounded through the support portion 92.

A plurality of ejection ports 91a which are open to the under surface are formed in the disk-like gas ejection portion 91 constituting the upper electrode 9. The plurality of ejection ports 91a are connected to a gas supply means 16 through a communication path 91b formed in the gas ejection portion 91 and a communication path 92a formed in the support portion 92. The gas supply means 16 supplies a plasma generating mixed gas essentially composed of a fluorine-based gas.

Keeping on describing with reference to FIG. 10 and FIG. 11, the plasma etching apparatus 5 in the illustrated embodiment comprises a control means 17 for controlling the gate moving means 60, the gas exhaust means 11, the high-frequency power source 12, the suction means 13, the refrigerant supply means 14, the lifting drive means 15, the gas supply means 16 and the drive circuits 862 and 872 of the DC voltage application means 86 and 87. Data on the inside pressure of the closed space 50a formed by the housing 50, data on the temperature of the refrigerant (that is, the temperature of the electrode) and data on the flow rate of the gas are supplied to the control means 65 from the gas exhaust means 11, the refrigerant supply means 14 and the gas supply means 16, respectively. The control means 17 outputs a control signal to each of the above means based on the above data.

The plasma etching apparatus 5 in the illustrated embodiment is constituted as described above and a description is subsequently given of the etching step for making smooth the rough inner walls 271 of the via holes 27 formed by the above via hole forming step and removing the debris 272 accumulating around the openings of the via holes 27 on the rear surface 21b of the substrate 21, which is carried out by using the plasma etching apparatus 5.

To plasma etch the semiconductor wafer 2 which has undergone the via hole forming step by using the plasma etching apparatus 5, the gate moving means 60 is first activated to move down the gate 6 in FIG. 10 to open the opening 54a formed in the right side wall 54 of the housing 50. The semiconductor wafer 2 affixed to the protective member 20 is carried into the closed space 50a formed by the housing 50 from the opening 54a by the transfer means (not shown) and the protective member 20 side of the semiconductor wafer 2 is placed on the holding surface 81a of the chuck table 81 set in the lower electrode 7. At this point, the lifting drive means 15 is activated to move up the upper electrode 9. The suction means 13 is then activated to apply negative pressure to the holding surface 81a through the communication path 7a and the suction paths 81b in order to suction hold the semiconductor wafer 2 on the holding surface 81a through the protective member 20.

After the semiconductor wafer 2 is suction held on the holding surface 81a of the chuck table 81 through the protective member 20, the drive circuits 862 and 872 of the DC voltage application means 86 and 87 are turned on to apply positive (+) voltage to the electrode 82 and negative (−) voltage to the electrode 83, respectively. As a result, positive (+) and negative (−) charges are generated between the holding surface 81a of the chuck table 81 and the protective member 20 bonded to the semiconductor wafer 2 suction held on the holding surface 81a so that the semiconductor wafer 2 is electrostatically absorbed onto the holding surface 81a through the protective member 20 by Johnsen-Rahbek force applied therebetween. After the semiconductor wafer 2 is suction held on the holding surface 81a of the chuck table 81 through the protective member 20, the operation of the suction means 13 is stopped to cancel the suction holding of the semiconductor wafer 2 by negative pressure. The reason why the semiconductor wafer 2 is suction held on the holding surface 81a of the chuck table 81 by negative pressure before it is electrostatically absorbed onto the holding surface 81a is that the semiconductor wafer 2 is positioned surely on the holding surface 81a before it is electrostatically absorbed onto the holding surface 81a.

After the semiconductor wafer 2 is electrostatically absorbed onto the holding surface 81a of the chuck table 81 through the protective member 20, the gate moving means 60 is activated to move up the gate 6 in FIG. 10 to close the opening 54a formed in the right side wall 54 of the housing 50. The lifting drive means 15 is then activated to move down the upper electrode 9 to reduce the distance between the under surface of the gas ejection portion 91 constituting the upper electrode 9 and the top surface of the semiconductor wafer 2 held on the holding surface 81a of the chuck table 81 set in the lower electrode 7 through the protective member 20 to a predetermined value (D) suitable for plasma etching as shown in FIG. 12. The distance between the electrodes is set to 10 mm in the illustrated embodiment.

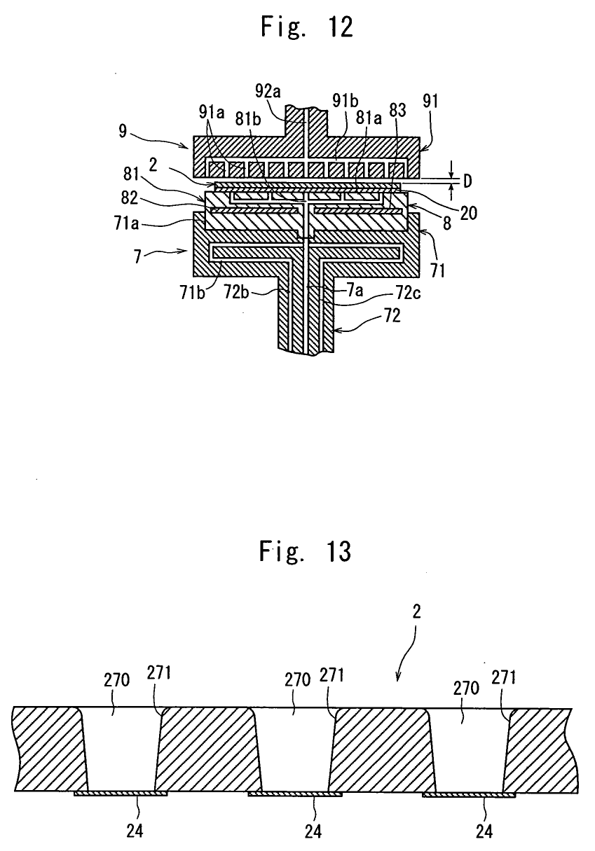

The gas exhaust means 11 is then activated to evacuate air from the inside of the closed space 50a formed by the housing 50. After air is evacuated from the inside of the closed space 50a, the gas supply means 16 is activated to supply a plasma generating gas to the upper electrode 9. The plasma generating gas supplied from the gas supply means 16 is applied to the rear surface (top surface) 21b of the substrate 21 of the semiconductor wafer 2 held on the holding surface 81a of the chuck table 81 through the protective member 20 from the plurality of ejection ports 91a through the communication path 92a formed in the support portion 92 and the communication path 91b formed in the gas ejection portion 91. The inside gas pressure of the closed space 510 is maintained at a predetermined value. A high-frequency voltage is applied between the lower electrode 7 and the upper electrode 9 from the high-frequency power source 12 while the plasma generating gas is supplied. Thereby, plasma is generated in the space between the lower electrode 7 and the upper electrode 9 so that an active substance generated by this plasma functions to the rear surface 21b (top surface) of the substrate 21 of the semiconductor wafer 2, whereby the rear surface 21b of the substrate 21 of the semiconductor wafer 2 is etched and also the rough inner walls 271 of the via holes 27 formed in the substrate 21 are etched. As a result, grinding distortion which is generated in the rear surface 21b of the substrate 21 of the semiconductor wafer 2 in the above rear surface grinding step is removed, the debris 272 which accumulates around the openings of the via holes 27 by carrying out the above via hole forming step is removed as shown in FIG. 13, and further the rough inner walls 271 of the via holes 27 are made smooth, thereby forming via holes 270 having a smooth inner wall. In addition to the above, when the via holes 27 reaching the bonding pads 24 are formed in the above via hole forming step, as the laser beam is slightly applied to the rear surfaces of the bonding pads 24, metal atoms forming the bonding pads 24 are scattered to become metal contaminants which adhere to the inner walls 271 of the via holes 27 and diffuse into the inside of the substrate made of silicon to decrease the quality of each device. The metal atoms adhering to the inner walls 271 of the via holes 27 are also removed by carrying out the above etching step. Even when the via holes formed in the substrate 21 of the semiconductor wafer 2 do not reach the bonding pads 24 and the remaining portions 28 exist in the via hole forming step as shown in FIG. 9(a), the remaining portions 28 of the via holes 27 are etched by carrying out the above etching step to form via holes reaching the bonding pads 24. When the remaining portions 2 of the via holes 2 are etched to form via holes reaching the bonding pads 24, the rear surfaces of the bonding pads 24 are not damaged. Since a fluorine-based gas is used as the plasma generating gas in the above etching step, the bonding pads 24 made of a metal material such as aluminum or the like are not etched.

The above etching step is carried out under the following conditions, for example.
Output of power source 68: 2000 W
Inside pressure of closed space 50a: 80 Pa
Plasma generating gas: 76 ml/m of sulfur hexafluoride (SF₆),
   15 ml/min of helium (He) and 27 ml/m of oxygen (O₂), or,
   76 ml/m of sulfur hexafluoride (SF₆), 15 ml/min of methyl trifluoride (CHF₃) and 27 ml/m of oxygen (O₂),
   or,
   76 ml/m of sulfur hexafluoride (SF₆), 15 ml/min of nitrogen (N₂) and 27 ml/m of oxygen (O₂)
Etching time: 3 minutes

After the above etching step, the operation of the gas supply means 16 is stopped and the high-frequency power source 12 is turned off. Next, the gate moving means 60 is activated to move down the gate 6 in FIG. 10 to open the opening 54a formed in the right side wall 54 of the housing 50. The drive circuits 862 and 872 of the DC voltage application means 86 and 87 of the electrostatic chuck table mechanism 8 are then turned off. As a result, the Johnsen-Rahbek force applied between the holding surface 81a of the chuck table 81 and the protective member 20 affixed to the semiconductor wafer 2 suction held on the holding surface 81a is canceled. The semiconductor wafer 2 bonded to the protective member 20 can be easily taken away from the holding surface 81a of the chuck table 81 by the transfer means that is not shown.

The above etching step is carried out by using the plasma etching apparatus 5. However, wet etching may be carried out in the etching step.

What is claimed is:

1. A method of forming a via hole reaching a bonding pad in a wafer, which have a plurality of devices on the front surface of a substrate and bonding pads on each of the devices by applying a pulse laser beam from the rear surface of the substrate, comprising the steps of:
affixing a protective member to the front surface of the substrate;
grinding the rear surface of the substrate having the protective member affixed to the front surface to reduce the thickness of the wafer to a predetermined value;
forming via holes in the substrate by applying a pulse laser beam from the rear surface of the substrate of the wafer having the predetermined thickness; and
etching the wafer having the via holes in the substrate from the rear surface of the substrate.

2. The via hole forming method according to claim 1, wherein plasma etching is carried out in the etching step.

3. The via hole forming method according to claim 1, wherein the wafer has a device area where the plurality of devices are formed and a peripheral excess area surrounding the device area on the front surface of the substrate, and the rear surface grinding step is to grind an area corresponding to the device area on the rear surface of the substrate so as to reduce the thickness of the wafer to a predetermined value and to keep an area corresponding to the peripheral excess area on the rear surface of the substrate as an annular reinforcing portion.

4. The via hole forming method according to claim 1, wherein the via hole forming step is to form via holes not reaching the bonding pads, leaving the remaining portions behind, and the etching step is to form via holes reaching the bonding pads by etching the remaining portions.
